(19) United States
(12) Patent Application Publication
(10) Pub. No.: US 2003/0013307 A1
(43) Pub. Date: Jan. 16, 2003

(54) Method of fabricating a self-aligned landing via

(76) Inventor: Chin-Fu Lin, Taichung Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,052

(22) Filed: Jul. 16, 2001

(51) Int. Cl. H01L 21/311

(52) U.S. Cl. 438/694

(57) ABSTRACT

A method of fabricating a self-aligned landing via is provided. A plurality of word lines and active areas are laid out on a semiconductor substrate. Two neighboring word lines pass through the active area to form both a landing via region at the portion overlapping with the active area and a gap-filling region at the portion outside the active area. Then, a spacer is formed on either side of the word line. The spacer is thick enough to fill the gap-filling region but not enough to fill the landing via region so as to form a self-aligned landing via hole. Finally, a conductive layer is filled within the landing via hole to form a landing via.

### BACKGROUND OF INVENTION

1. Field of the Invention

The present invention relates to a method of fabricating a self-aligned landing via, and more particularly, to a method of designing a special layout of word lines combined with an etching back process of spacers to produce a self-aligned landing via.

2. Description of the Prior Art

A dynamic random access memory (DRAM) cell comprises a metal-oxide-semiconductor (MOS) transistor, a capacitor and a contact plug. A landing via is used as a contact plug to electrically connect the MOS transistor to the capacitor. As the component size of semiconductor devices shrinks, it becomes more difficult to form a smaller landing via without affecting the efficiency of the MOS transistor. Therefore, it becomes increasingly important to improve the structure and fabricating processes of the landing via so as to increase the production yield.

Please refer to FIG. 1 and FIG. 2. FIG. 1 and FIG. 2 are schematic diagrams of a method of fabricating a self-aligned landing via 28 according to the prior art. As shown in FIG. 1, a plurality of word lines 20 are formed as gates of transistors on a substrate 12 of a semiconductor wafer 10. Each word line 20 is a stacked layer composed of a doped polysilicon layer 14, a silicide layer 16 and a capping layer 18, respectively, on the surface of the substrate 12. A spacer 22 is also formed on either vertical side wall of the word line 20.

As shown in FIG. 2, a dielectric layer 24 of silicon dioxide (SiO₂) is then deposited on the surface of the substrate 12 to completely cover the word line 20. A photoresist layer (not shown) is formed on the dielectric layer 24, followed by the use of a photolithographic process to define both the position and pattern of a landing via hole in the photoresist layer. Subsequently, an anisotropic etching process is performed to etch the dielectric layer 24 down to the surface of the substrate 12 along the pattern of the photoresist layer so as to form a landing via hole 26. After the photoresist layer is completely removed, a doped polysilicon layer (not shown) is deposited on the semiconductor wafer 10 to fill the landing via hole 26. Finally, an etching back process is performed to remove the doped polysilicon layer outside the landing via hole 26, with the remaining doped polysilicon layer within the landing via hole 26 functioning as a conductor to finish fabrication of the landing via 28.

The top and vertical side walls of the word line 20 are covered with the capping layer 18 and the spacers 22, respectively, of silicon nitride to increase mis-alignment tolerances during the etching process of defining the landing via hole 26. As a result, a self-aligned contact (SAC) etching technique is used to fabricate the landing via 28. However, the process window of etching the landing via hole 26 shrinks as element integration increases. Defining patterns of the landing via hole 26 in the photoresist layer is also restricted by a resolution limit of the optical exposure tools. Thus, fabrication of the landing via 28 becomes subsequently difficult. When performing the etching process to define the landing via hole 26, the etching selectivity between the spacer 22 (silicon nitride) and the dielectric layer 24 (silicon dioxide) is usually not sufficient enough and leads to damage to the spacer 22. Use of the damaged spacer 22 in isolating the doped polysilicon layer 14 and the suicide layer 16 from the conductor within the landing via 28 is thus very unreliable.

### SUMMARY OF INVENTION

It is therefore an objective of the present invention to provide a method of fabricating a self-aligned landing via to overcome difficulties resulting from the narrow process window.

It is another objective of the present invention to provide a method of fabricating a self-aligned landing via to prevent damage to the spacer and thus improve the electrical performance of the semiconductor elements.

In a preferred embodiment of the present invention, a semiconductor substrate is provided with both a defined peripheral region and a cell array region. A plurality of word lines and active areas are laid out in the cell array region of the semiconductor substrate. Two neighboring word lines pass through the active area and form both a landing via region at the portion overlapping the active area and a gap-filling region at the portion outside the active area. A spacer is formed on either side of the word line. The spacer is thick enough to fill the gap-filling region but not enough to fill the landing via region so as to form a self-aligned landing via hole. A conductive layer is then filled within the landing via hole to form a landing via.

It is an advantage of the present invention that a special layout pattern is used to define positions of both the word lines and the active areas. A method of fabricating the spacer is also used to fill the gap-filling region so as to form the self-aligned landing via hole in the landing via region. Conventional photolithographic processes are thus unnecessary to define the pattern of the landing via. As a result, process window problems resulting from the resolution limits are completely prevented. As well, the present invention uses a multi-spacer structure to isolate the word line from the conductor within the landing via, so that short-circuiting due to damage of the single spacer, as in the prior art, does not occur.

These and other objectives of the present invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 and FIG. 2 are schematic diagrams of a prior art method of fabricating a self-aligned landing via.

FIG. 3 to FIG. 8 are schematic diagrams of fabricating a self-aligned landing via according to the present invention.

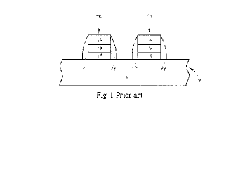

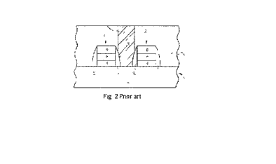

### DETAILED DESCRIPTION

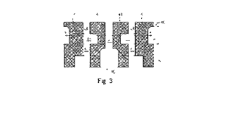

Please refer to FIG. 3 to FIG. 8. FIG. 3 to FIG. 8 are schematic diagrams of fabricating a self-aligned landing via 62. As shown in FIG. 3, patterns of a plurality of active areas 40 and word lines 44 are laid out and defined on a semiconductor substrate 30. Therein, a peripheral region and a cell array region are pre-defined on the semiconductor substrate 30. For convenient specification of the present invention, only a cross-sectional view of the cell array region is shown in FIG. 3 to FIG. 8 to illustrate the relative art.

In a preferred embodiment of the present invention, the semiconductor substrate 30 is a P-type single crystal silicon substrate with a <100> surface. Alternatively, the semiconductor substrate is a silicon-on-insulator (SOI) substrate, an epitaxy silicon substrate or any other silicon substrate of various lattice structures.

As shown in FIG. 3, the word lines 44 and the active areas 40 are positioned in perpendicular. The overlapping region of gaps between any two word lines 44 with the active areas 40 form a landing via region 46. Simultaneously, the gaps between any two word lines 44 not overlapping with the active areas 40 form a gap-filling region 48. The landing via region 46 is noticeably wider than the gap-filling region 48. Layout patterns of the word lines 44 are formed so that each word line 44 is wider outside the active area 40 while narrower at the portion overlapping with the active area 40. Such a structure produces a wider landing via region 46 and a narrower gap-filling region 48.

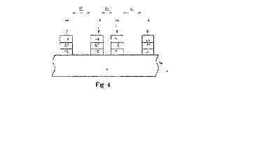

Please refer to FIG. 4. FIG. 4 is a sectional view along line AA″ shown in FIG. 3. As shown in FIG. 4, a plurality of word lines 44 are formed and isolated from one another using landing via regions 46 or gap-filling regions 48 on the semiconductor substrate 30 according to the layout pattern. The word line 44 is a stacked layer, composed of a gate oxide layer (not shown), doped polysilicon layer 50, a silicide layer 52 and a capping layer 54, respectively, on the surface of the semiconductor substrate 30. The cross-sectional structure of the word line 44 mentioned above is simply a better embodiment of the present invention, other structures of the word lines or gates can also be achieved.

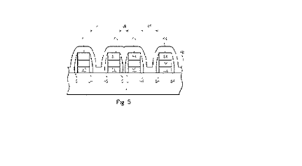

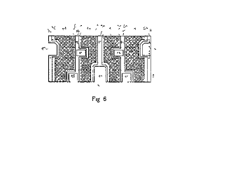

As shown in FIG. 5, a spacer 56 of silicon nitride is then formed on either side of the word line 44. The thickness of the spacer 56 is approximately 200 to 600 angstroms (Å). Subsequently, a chemical vapor deposition (CVD) process is performed to deposit a dielectric layer 58, such as a silicon nitride layer or a silicon dioxide layer, on the surface of the semiconductor substrate 30. The dielectric layer 58 is thick enough to fill the gap-filling region 48 but not enough to fill the landing via region 46, as shown in FIG. 6 of a top view of FIG. 5.

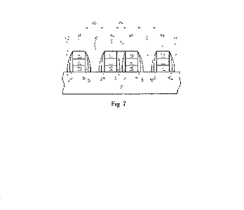

As shown in FIG. 7, an anisotropic dry etching process is then used to etch back a portion of the dielectric layer 58 so as to form a spacer 59 on the side wall of the word line 44 within the landing via region 46. The thickness of the spacer 59 is approximately 200 to 600 angstroms. Since the width of the gap-filling region 48 is smaller than that of the landing via region 46, the dielectric layer 58 filled within the gap-filling region 58 is not removed during the dry etching process. As a result, the gap between the spacers 59 in the landing via region 46 is enclosed to function as a self-aligned landing via hole 60.

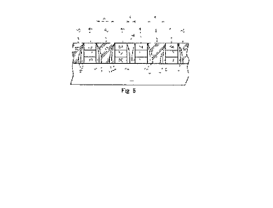

As shown in FIG. 8, a doped polysilicon layer (not shown) is deposited on the semiconductor substrate 30 to completely fill the landing via hole 60. Finally, an etching back process is performed to remove the doped polysilicon layer outside the landing via hole 60 so that the remaining doped polysilicon layer within the landing via hole 60 functions as a conductor to finish fabrication of the landing via 62. In other embodiments of the present invention, further steps are performed in forming a bit line or capacitor over the landing via 62 so that transistors may electrically connect to bit lines or capacitors using the landing via 62.

The present invention uses a special layout pattern of word lines to define the relative positions of the word lines and the active areas, so that a first and a second gap of different widths are formed between any two word lines. Moreover, a method of fabricating the spacer is used to fill the narrower first gap and to simultaneously form the self-aligned landing via hole in the wider second gap.

In contrast to the prior art of fabricating the self-aligned landing via, the present invention does not need the conventional photolithographic processes to define the pattern of the landing via. As a result, process window problems resulting from the resolution limits are completely prevented. As well, according to the present invention, at least two spacers are formed between the word line and the conductor within the landing via, so that short-circuiting as a result of damage of the single spacer of the prior art does not occur.

Those skilled in the art will readily observe that numerous modifications and alterations of the device may be made while retaining the teachings of the invention.

Accordingly, the above disclosure should be construed as limited only by the metes and bounds of the appended claims.

What is claimed is:

1. A method of fabricating a landing via on a semiconductor substrate, at least a peripheral region and a cell array region being defined on the semiconductor substrate, at least an active area being defined on the semiconductor substrate within the cell array region, the method comprising:
laying out at least two neighboring word lines on the semiconductor substrate in the cell array region, the word lines passing through the active area to form both a landing via region at the portion overlapping with the active area and a gap-filling region at the other portions outside the active area;
forming a first spacer on the either side of each of the two neighboring word lines, the first spacer being thick enough to fill the gap-filling region but not enough to fill the landing via region so as to form a self-aligned landing via hole;
forming a conductive layer on the semiconductor substrate to fill the landing via hole; and
performing an etching back process to remove the conductive layer outside the landing via hole to form the landing via.

2. The method of claim 1 wherein each of the word lines comprises both a stacked layer and a second spacer positioned on the either side of the stacked layer.

3. The method of claim 2 wherein the second spacer is composed of silicon nitride.

4. The method of claim 2 wherein the stacked layer is composed of a conductive layer and a capping layer, respectively.

5. The method of claim 3 wherein the second spacer is approximately 200 to 600 angstroms (Å) thick.

6. The method of claim 1 wherein the sapce between the two neighboring word lines is wider in the landing via region than in the gap-filling region.

7. The method of claim 1 wherein the landing via is electrically connected to a bit line.

8. The method of claim 1 wherein the landing via is electrically connected to a capacitor.

9. The method of claim 1 wherein the first spacer is composed of silicon nitride or silicon dioxide.

10. The method of claim 9 wherein the first spacer is approximately 200 to 600 angstroms thick.

11. A method of fabricating a landing via on a semiconductor substrate, the semiconductor substrate comprising a plurality of word lines positioned on the surface of the semiconductor substrate and a plurality of first gaps and second gaps enclosed by the word lines, the second gaps being wider than the first gaps, the method comprising:
forming a first spacer on the either side of each of the word lines to fill the first gaps and forming a self-aligned landing via hole in the second gaps;
forming a conductive layer on the semiconductor substrate to fill the landing via hole; and
performing an etching back process to remove the conductive layer outside the landing via hole to form the landing via.

12. The method of claim 11 wherein each of the word lines comprises a stacked layer and a second spacer positioned on the either side of the stacked layer.

13. The method of claim 12 wherein the second spacer is composed of silicon nitride.

14. The method of claim 12 wherein the stacked layer is composed of a conductive layer and a capping layer, respectively.

15. The method of claim 13 wherein the second spacer is approximately 200 to 600 angstroms (Å) thick.

16. The method of claim 11 wherein the landing via is electrically connected to a bit line.

17. The method of claim 11 wherein the landing via is electrically connected to a capacitor.

18. The method of claim 11 wherein the first spacer is composed of silicon dioxide.

19. The method of claim 18 wherein the first spacer is approximately 200 to 600 angstroms thick.
